(19) United States
(12) Patent Application Publication
(10) Pub. No.: US 2008/0304237 A1
(43) Pub. Date: Dec. 11, 2008

(54) ELECTRONIC COMPONENT BUILT-IN MODULE AND METHOD FOR MANUFACTURING THE SAME

(76) Inventor: Tsukasa SHIRAISHI, Osaka (JP)

Correspondence Address: MCDERMOTT WILL & EMERY LLP, 600 13TH STREET, NW, WASHINGTON, DC, 20005-3096, US

(21) Appl. No.: 12/131,439

(22) Filed: Jun. 2, 2008

(30) Foreign Application Priority Data
Jun. 7, 2007 (JP) 2007-151147

(51) Int. Cl. H05K 7/20; H01R 43/00; B29C 69/00

(52) U.S. Cl. 361/702; 29/825; 264/241

(57) ABSTRACT

On a first component built-in substrate having built-in electronic components, a second component built-in substrate having built-in electronic components is stacked, and further on the second component built-in substrate, a radiator is attached. The second component built-in substrate includes a wiring layer with electronic components mounted on a main surface thereof, and an insulating layer which is mainly composed of a mixture containing an inorganic filler and a thermosetting resin and in which the electronic components mounted on the wiring layer are embedded. The insulating layer of the second component built-in substrate conducts heat generated from the electronic components and the wiring layer to the radiator.

### FIELD OF THE INVENTION

The present invention relates to electronic component built-in modules in which electronic components are disposed in an electrically insulating substrate, and to a method for manufacturing the same.

### BACKGROUND OF THE INVENTION

With recent electronic devices becoming small, thin, and highly functional, electronic components to be mounted on a printed board have been required to be highly dense, and printed boards with electronic components mounted thereon have been required to be highly functional ever before. Under these circumstances, an electronic component built-in module, in which electronic components are embedded in a substrate, has been developed (for example, Japanese Patent Nos. 3375555 and 3547423).

In general printed boards, active components (for example, semiconductor element) and passive components (for example, capacitor) are mounted on the surface of the substrate. On the other hand, in the case of electronic component built-in modules, a three-dimensional circuit can be easily formed by stacking different printed boards and electronic component built-in modules three-dimensionally. Further, compared with the case of mounting components on one substrate, in the case of mounting components in a three-dimensional circuit, the same number of components can be mounted in a less area, i.e., the area necessary for mounting the components takes up approximately the same amount of area as one substrate, which is 1/the number of stacked substrates. Further, with three-dimensional circuits, the two-dimensional distance between the components can be made short. As a result, with optimization of wiring between the electronic components, high-frequency characteristics can also be improved, since the degree of freedom in disposing components increases compared with the case where electronic components are mounted on the surface of the printed board.

With reference to FIG. 6, the electronic component built-in module disclosed in the above Patent Documents is described. An electronic component built-in module 400 includes an insulating substrate 401, and wiring layers 402a and 402b . Electronic components 404a and 404b are disposed on a main surface of the wiring layer 402a and connected thereto with solder 405a and 405b. Similarly, electronic components 404c, 404d, and 404e are disposed on a main surface of the wiring layer 402b and connected thereto with solder 405c , 405d, and 405e.

The wiring layer 402a and the wiring layer 402b are disposed so as to be substantially parallel with the insulating substrate 401 interposed therebetween, so as to allow the faces thereof with the electronic components mounted (in FIG. 6, upper face) to be oriented in the same direction.

That is, in this example, the electronic components 404a and 404b mounted on the wiring layer 402a are embedded in the insulating substrate 401, thereby achieving highly dense components assembly. Further, in the insulating substrate 401, inner vias 403a, 403b, and 403c are provided to secure electric connection between the wiring layers 402a and 402b.

To briefly describe materials of each element, the insulating substrate 401 is mainly composed of a mixture containing an inorganic filler and a thermosetting resin. The wiring layers 402a and 402b are formed of electrically conductive materials, for example, copper foil and a conductive resin composition. The inner vias 403a, 403b, and 403c are made of, for example, a thermosetting conductive material. For the thermosetting conductive material, for example, a conductive resin composition in which metal particles and a thermosetting resin are blended is used.

With recent development in semiconductor processes, the amount of heat generation from semiconductor components is rapidly increasing, and the heat-release measures have been an issue. The above-described electronic component built-in module 400 is intended for mounting of the semiconductor components. Since the semiconductor components to be mounted on the wiring layer 402a are embedded in the insulating substrate 401, the heat-release measures to actively release heat in the module to the outside are essential.

FIG. 7 shows a structure of a conventional electronic component built-in module 500 provided with heat-release measures. In the electronic component built-in module 500, a multilayer wiring substrate 411a is provided on the lower face of the wiring layer 402a of the above-described electronic component built-in module 400 (FIG. 6). On the lower face of the multilayer wiring substrate 411a, a wiring layer 402c is provided. The wiring layers 402a and 402c are connected to each other by wiring (not shown) provided inside the wiring substrate 411a.

Further, on the lower face of the wiring layer 402b , in the same fashion as in the wiring layer 402a, a multilayer wiring substrate 411b and a wiring layer 402d are provided. The wiring layers 402b and 402d are connected to each other by wiring (not shown) provided inside the wiring substrate 411b. The wiring layer 402d is connected to the inner vias 403a, 403b, and 403c.

On the upper side of the wiring layer 402b , a heat-release sheet 406 and a heat sink (radiator) 407 are provided. The heat-release sheet 406 and the heat sink 407 are fixed to the wiring layer 402b or to the wiring substrate 411b by bonding or screwing. In the heat-release sheet 406, recess portions (space) for storing the electronic components 404c, 404d, and 404e, and the solder 405c and 405e are provided. These recess portions are formed to have a size bigger than the external shape of the components to be stored.

In the electronic component built-in module 500, the heat generated by the electronic components 404a to 404e, i.e., heat source, is guided to the heat sink 407 via the heat-release sheet 406 mainly by heat conduction, and is released into air from the heat sink 407. In the following, the heat-releasing mechanism of the electronic component built-in module 500 is described in detail.

First, the heat-release mechanism for the heat generated from the electronic components 404a and 404b is described. In the electronic components 404a and 404b embedded in the insulating substrate 401, a great amount of heat is generated particularly from a semiconductor package component. As a measure to release the heat, a great amount of an inorganic filler is added to the insulating substrate 401 to improve heat conduction. The heat generated from the electronic components 404a and 404b is dissipated into the insulating substrate 401 by heat conduction, and then conducted to the upper face of the wiring substrate 411b via the wiring layer 402d , the wiring in the wiring substrate 411b, and the wiring layer 402b , which easily conduct heat. The heat conducted to the upper face of the wiring substrate 411b is conducted to the heat sink 407 via the heat-release sheet 406 contacting the wiring substrate 411b, and then released into air.

Next, the heat-release mechanism for the heat generated from the electronic components 404c to 404e is described. In the heat-release sheet 406, recess portions are formed according to the shape of the electronic components 404c to 404e, and the rear face and the side face of the electronic components 404c to 404e are partially in contact with the heat-release sheet 406. The heat generated from the electronic components 404c to 404e is conducted to the heat sink 407, and is released into air via the portion contacting the heat-release sheet 406. By forming the recess portions in the heat-release sheet 406 according to the shape of the electronic components, the contact area between the heat-release sheet 406, and the electronic components 404c to 404e increases, thereby increasing the heat conduction amount.

Next, with reference to FIG. 8, a method for manufacturing the electronic component built-in module 500 shown in FIG. 7 is briefly described. As shown in FIG. 8(a), a mixture of an inorganic filler and a thermosetting resin in an uncured state is processed into a sheet form, thereby forming the insulating substrate 401. Then, through holes are formed at predetermined positions of the insulating substrate 401, and a thermosetting conductive material is filled in the through holes, to form the inner vias 403a to 403c.

Separately, as shown in FIG. 8(b), referring to the prepared multilayer wiring substrates 411a and 411b, the electronic components 404a and 404b are mounted in advance on the wiring layer 402a formed on a main surface of the wiring substrate 411a.

Then, as shown in FIG. 8(c), at a predetermined position of the main surface of the wiring substrate 411a, the insulating substrate 401 is placed in a predetermined orientation, and further, the wiring substrate 411b is placed at a predetermined position in a predetermined orientation thereon. Thereafter, the wiring substrate 411a, the insulating substrate 401, and the wiring substrate 411b are sandwiched by heat-press plates 408a and 408b, and pressure and heat treatment is carried out in such a state.

At the time of the pressure and heat treatment as shown in FIG. 8(d), the pressure is applied by the heat-press plates 408a and 408b in the direction of the arrows, and the electronic components 404a and 404b are embedded in the insulating substrate 401. Afterwards, the thermosetting resin in the insulating substrate 401, and the inner vias 403a to 403c is cured, thereby integrating the wiring substrate 411a, the insulating substrate 401, and the wiring substrate 411b. Upon the integration, the inner vias 403a to 403c are connected to the wiring layers 402a and 402d .

Afterwards, as shown in FIG. 8(e), on the wiring layer 402b , the electronic components 404c to 404e are mounted by using solder.

Lastly, as shown in FIG. 8(f), the heat-release sheet 406 with the recess portions formed in advance according to the shape of the electronic components 404c to 404e, and the heat sink 407 are placed in order at a predetermined position and in a predetermined orientation, and then fixed. The electronic component built-in module 500 provided with heat-release measures as shown in FIG. 8(g) is thus obtained.

In the conventional heat-release structure using the heat-release sheet 406 as described above, the recess portions have to be formed in the heat-release sheet 406 according to the position and shape of the electronic components to be mounted on the wiring layer 402b. However, since the position and shape of the electronic components are various depending on modules, the position and the size of the recess portions to be formed on the heat-release sheet have to be changed at every manufacturing occasion. As a result, costs for manufacturing the electronic component built-in module increase.

Further, forming the recess portions corresponding to the contour of the electronic components (404c to 404e) to be mounted in the heat-release sheet 406 leads to an increase in costs of the heat-release sheet. Therefore, for the recess portions, relatively workable shapes such as rectangular parallelepiped and cylindrical shape are used. Additionally, the size of the recess portions to be formed in the heat-release sheet 406 should be slightly larger than the components to be enclosed, considering variations in the mounting positions of the electronic components, contours of the components, and further the amount of the solder material overflowed.

As a result, the area where the electronic components (404c to 404e) are in contact with the heat-release sheet 406 becomes limited, and a relatively large air layer is formed between the electronic components and the heat-release sheet 406. The heat generated from the electronic components is dissipated by heat conduction mainly via the portion thereof contacting the heat-release sheet 406. With a great amount of the air layer, the amount of the heat conduction to the heat-release sheet 406 decreases accordingly.

Additionally, based on the variation in height of the electronic components after being mounted, sometimes the rear face (upper face in the drawings) of the electronic components is not brought into contact with the heat-release sheet 406. In such a case, the heat conduction amount is further decreased. Particularly, when the electronic component is a semiconductor package component with a great amount of heat generation such as CPU, with the small contact area at the rear face of the electronic component, abnormal temperature increase is caused, which may be a cause for malfunction during operation and failure in the semiconductor package component.

Further, depending on the kind of the semiconductor package component, the temperature sometimes increases to about 100° C. during operation. Usually, the heat-release sheet 406 is attached to the wiring substrate 411b, and therefore the air layer in the recess portions exists in a closed space. Therefore, with a temperature increase in the electronic components, the air layer is heated and expanded. In the worst case, the pressure in the air layer sometimes causes damage to the electronic components, and causes the heat-release sheet 406 to be peeled from the wiring substrate 411b, to deteriorate moisture resistance characteristics.

FIG. 7 shows an example of an electronic component built-in module in which two wiring substrates with the electronic components mounted are stacked. In the future, in response to a demand for highly dense mounting, it is highly possible that an electronic component built-in module in which three or more wiring substrates are stacked will be developed. The more the number of the wiring substrates to be stacked, the more the total amount of heat generated from the electronic components. In a multi-layer electronic component built-in module, the heat released from a lower wiring substrate is conducted to the uppermost wiring substrate mainly via the wiring in each layer. The heat conducted to the wiring in the uppermost layer is conducted to the heat sink via the heat-release sheet contacting the wiring.

Therefore, in order to increase the amount of the heat released from the heat sink to the outside, the area of the heat-release sheet contacting the wiring has to be increased. However, the area of the heat-release sheet contacting the wiring is determined in relation to the mounting density, and it cannot be easily increased. Thus, there are limitations in conducting the amount of heat generated in the lower wiring substrate to the heat sink.

Further, in the processes for manufacturing an electronic component built-in module, a process of working a heat-release sheet, and a process of placing and fixing the heat-release sheet and the heat sink have to be added. Such an addition of the processes is a factor for the increase in the manufacturing costs for the electronic component built-in module.

### BRIEF SUMMARY OF THE INVENTION

Thus, the present invention aims for providing an electronic component built-in module with excellent heat-release characteristics, with fewer the processes to be added for the heat-release measures.

To achieve the above aim, an electronic component built-in module according to the present invention includes a first component built-in substrate having built-in electronic components, a second component built-in substrate having built-in electronic components stacked on the first component built-in substrate, and a radiator attached on the second component built-in substrate,

wherein the first component built-in substrate includes:

a first wiring layer with electronic components mounted on a main surface thereof, and a first insulating layer,
which is mainly composed of a mixture containing an inorganic filler and a thermosetting resin, and
in which the electronic components mounted on the first wiring layer are embedded, and inner vias for electric connection are formed; and

the second component built-in substrate includes:

a second wiring layer with electronic components mounted on a main surface thereof, and

a second insulating layer,
which is mainly composed of a mixture containing an inorganic filler and a thermosetting resin, and
in which the electronic components mounted on the second wiring layer are embedded.

A method for manufacturing an electronic component built-in module in accordance with the present invention includes the steps of:

preparing first and second wiring layers with electronic components mounted on respective main surfaces thereof;

preparing a first insulating layer by molding a mixture containing an inorganic filler and a thermosetting resin in an uncured state into a sheet, forming through holes in the first insulating layer, and filling a thermosetting conductive material in an uncured state into the through holes;

preparing a second insulating layer by molding a mixture containing an inorganic filler and a thermosetting resin in an uncured state into a sheet;

stacking the first wiring layer, the first insulating layer, the second wiring layer, and the second insulating layer with positions of respective layers aligned, and the main surfaces of the first wiring layer and the second wiring layer with the electronic components mounted thereon facing upward; and

applying heat and pressure to the first wiring layer, the first insulating layer, the second wiring layer, and the second insulating layer stacked and sandwiched by a pair of heat-press plates for integration.

Based on the present invention, the processes and the members that have been necessary for the heat-release measures can be reduced, and excellent heat-release characteristics can be brought out along with an improvement in internal heat conduction properties. As a result, a high performance and high quality electronic component built-in module can be provided at low-cost.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE SEVERAL VIEWS OF THE DRAWING

FIG. 1 is a cross sectional view of an electronic component built-in module in Embodiment 1 of the present invention.

FIG. 2 is a schematic diagram illustrating main processes for manufacturing the electronic component built-in module of FIG. 1.

FIG. 3 is a schematic diagram illustrating main processes for manufacturing an electronic component built-in module in Embodiment 2 of the present invention.

FIG. 4 is a cross sectional view of an electronic component built-in module in Embodiment 3 of the present invention.

FIG. 5 is a schematic diagram illustrating main processes for manufacturing the electronic component built-in module of FIG. 4.

FIG. 6 is a cross sectional view illustrating a structure of an example of an electronic component built-in module.

FIG. 7 is a cross sectional view of a conventional electronic component built-in module provided with heat-release measures.

FIG. 8 is a schematic diagram illustrating main processes for manufacturing the electronic component built-in module of FIG. 7.

### DETAILED DESCRIPTION OF THE INVENTION

### Embodiment 1

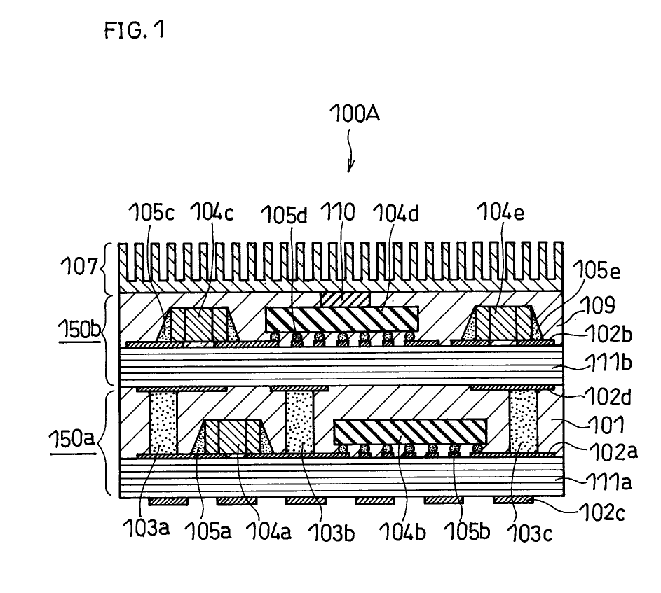

FIG. 1 shows a structure of an electronic component built-in module in Embodiment 1 of the present invention. In an electronic component built-in module 100A in this embodiment, a component built-in substrate 150b is stacked on a component built-in substrate 150a, and a heat sink 107, i.e., a radiator, is attached thereon.

The component built-in substrate 150a includes a wiring substrate 111a with a wiring layer 102a formed on its upper face and a wiring layer 102c formed on its lower face, and an electrical insulating layer (hereinafter abbreviated as “insulating layer”) 101 formed on the wiring substrate 111a.

Inside the insulating layer 101, electronic components 104a and 104b connected to the wiring layer 102a by solder 105a and 105b are embedded. Also, in the insulating layer 101, inner vias 103a, 103b, and 103c are provided, for electrically connecting the wiring layer 102a and a wiring layer 102d of the component built-in substrate 150b, which will be described later.

The insulating layer 101 is mainly composed of a mixture containing an inorganic filler and a thermosetting resin. As described above, the inorganic filler is a material excellent in heat conduction. For the inorganic filler, for example, Al₂O₃, MgO, BN, AlN, or SiO₂ can be used. The inorganic filler is preferably 70 wt % to 95 wt % relative to the mixture.

For the thermosetting resin, for example, highly heat-resistant epoxy resin, phenol resin, or cyanate resin is preferable. The mixture may further include a dispersing agent, a coloring agent, a coupling agent, or a parting agent.

The wiring layers 102a and 102c include a material with electrical conductivity, for example, copper foil and a conductive resin composition. The inner vias 103a, 103b, and 103c include, for example, a thermosetting conductive material. For the thermosetting conductive material, for example, a conductive resin composition in which metal particles and a thermosetting resin are blended is used.

The component built-in substrate 150b basically has the same structure as the component built-in substrate 150a. That is, it includes a wiring substrate 111b with a wiring layer 102b formed on its upper face and a wiring layer 102d formed on its lower face, and an insulating layer 109 formed on the wiring substrate 111b.

Inside the insulating layer 109, electronic components 104c, 104d, and 104e connected to the wiring layer 102b by solder 105c, 105d, and 105e are embedded. The insulating layer 109 also is mainly composed of, similarly to the insulating layer 101, a mixture containing an inorganic filler and a thermosetting resin. The wiring layers 102b and 102d comprise a material with electrical conductivity, for example, copper foil and a conductive resin composition.

Although not shown, wiring that connects the wiring layers 102a and 102c is formed inside the wiring substrate 111a. Similarly, wiring that connects the wiring layers 102b and 102d is formed inside the wiring substrate 111b as well.

Of the stacked two component built-in substrates, the component built-in substrate 150a on the lower side is nothing different from that of the conventional electronic component built-in module 500 as shown in FIG. 7. What is different from the conventional electronic component built-in module 500 is the structure of the component built-in substrate 150b on the upper side.

As described above, in the conventional electronic component built-in module 500, the heat-release sheet 406 is used as a means for conducting heat generated from the electronic components to the heat sink 407. On the other hand, in the electronic component built-in module 100A of this embodiment, the insulating layer 109 formed on the wiring substrate 111b is used as a means for conducting heat generated from the electronic components and the wiring layers to the heat sink 107.

Since the inorganic filler is added to the insulating layer 109 in a great amount, its heat conduction is excellent. The electronic components 104c to 104e are embedded in the insulating layer 109, and there is almost no gap between the electronic components 104c to 104e, and the insulating layer 109. That is, since an area where the electronic components are in contact with the insulating layer is large, heat generated from the electronic components and the wiring layers is dissipated in the insulating layer 109 by heat conduction efficiently, and conducted to the heat sink 107.

With almost no space between the wiring layer 102b and the insulating layer 109 as well, heat generated from the component built-in substrate 150a and conducted to the wiring layer 102b via the wiring layer 102d and the wiring in the wiring substrate 111b is dissipated in the insulating layer 109 efficiently and conducted to the heat sink 107.

Further, in the insulating layer 109, a thermal via 110 is formed at the portion in contact with the electronic component (for example, semiconductor package component) 104d where heat is generated in a great amount. To be specific, a material with excellent heat conduction properties (for example, a mixture of aluminum alloy powder and epoxy resin) is filled into the recess portions formed on the surface of the insulating layer 109. Due to the excellent heat conduction properties of the thermal via 110, heat from the electronic components 104d can be efficiently conducted to the heat sink 107.

Also, since the insulating layer 101 and the insulating layer 109 are formed of the same material, as described later, when the insulating layer 101 of the component built-in substrate 150a is formed, the insulating layer 109 can be formed at the same time. Therefore, a process of forming recess portions in the heat-release sheet, and a process of placing the heat-release sheet on the module are unnecessary.

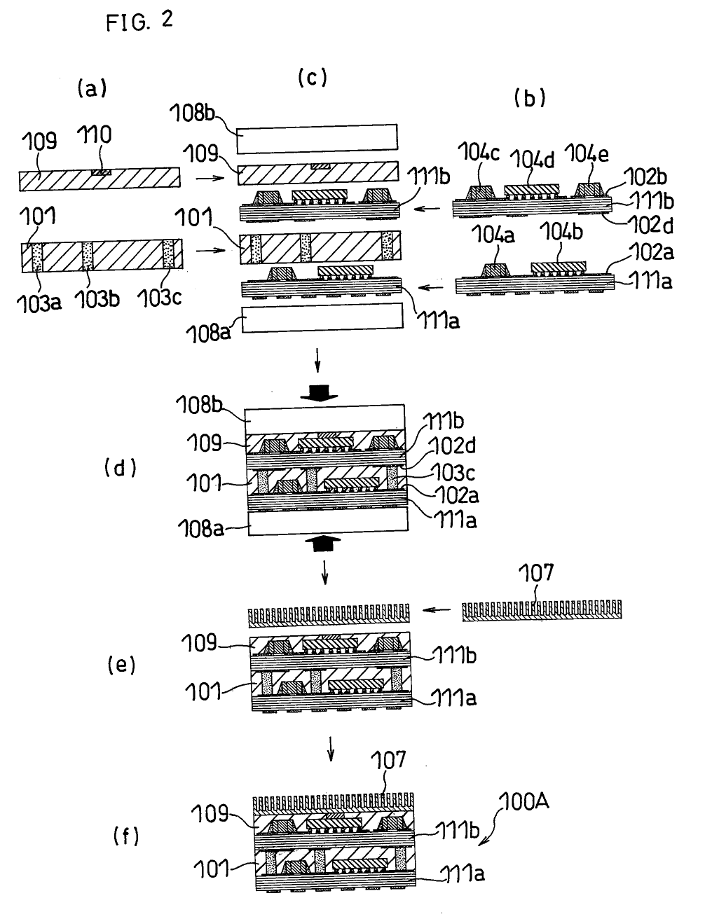

Then, with reference to FIG. 2, a method for manufacturing an electronic component built-in module 100A will be described. FIGS. 2(a) to 2(f) schematically show main processes for manufacturing the electronic component built-in module 100A.

As shown in FIG. 2(a), first of all, to improve heat conduction properties, a mixture of a great amount (for example, 80% wt) of an inorganic filler (for example, alumina powder) and an uncured thermosetting resin (for example, epoxy resin) is molded to prepare a sheet insulating layer 101 with excellent heat conduction properties. In this insulating layer 101, through holes are formed at predetermined positions, and a conductive paste (for example, a mixture of epoxy resin and copper powder) is filled into the through holes to form inner vias 103a to 103c.

Further, as shown in FIG. 2(a), the same mixture as used for the insulating layer 101 is molded to prepare a sheet insulating layer 109 with excellent heat conduction properties. A recess portion with a predetermined depth is formed in a predetermined position of the insulating layer 109, and a highly heat-conductive paste is filled into the recess portion, to form a thermal via 110.

Separately, as shown in FIG. 2(b), a multilayer wiring substrate 111a in which electronic components 104a and 104b are mounted on a wiring layer 102a is prepared. Also, another multilayer wiring substrate 111b in which electronic components 104c to 104e are mounted on a wiring layer 102b is prepared. Respective wiring layers and electrodes of the electronic components are connected by solder.

Then, as shown in FIG. 2(c), the insulating layer 101 is placed at a predetermined position of a main surface of the wiring substrate 111a in a predetermined orientation, and further thereon, the wiring substrate 111b and the insulating layer 109 are placed in order at a predetermined position in a predetermined orientation. Afterwards, these wiring substrate and insulating layer are sandwiched by heat-press plates 108a and 108b, and in such a state, pressure and heat treatment is carried out.

As shown in FIG. 2(d), at the time of pressure and heat treatment, the pressure is applied by the heat-press plates 108a and 108b in the direction of the arrows, so that the electronic components 104a to 104e are embedded in the insulating layers 101 and 109. Thereafter, the thermosetting resin in the insulating layer 101 and the inner vias 103a to 103c, the thermosetting resin in the insulating layer 109, and the thermosetting resin in the thermal via 110 are cured, thereby integrating the wiring substrates and the insulating layers. At the same time with the integration, inner vias 103a to 103c are connected to the wiring layers 102a and 102d.

Lastly, as shown in FIG. 2(e), a heat sink 107 is placed at a predetermined position of the uppermost portion in a predetermined orientation, and then fixed (for example, by screwing). The electronic component built-in module 100A with heat-release measures as shown in FIG. 2(f) is thus obtained.

As described above, since the highly heat conductive insulating layer 109 can be brought into close contact with the electronic components 104c to 104e almost without gaps in this embodiment, heat conduction with a broad contact area and little loss can be achieved. Additionally, a process for working a heat-release sheet and a process for fixing the heat-release sheet, which have been necessary conventionally, become unnecessary.

In this embodiment, since the same mixture is used for the insulating layers 101 and 109, the insulating layer 101 and the insulating layer 109 are formed at the same time. With the same material for both of the insulating layers, conditions for pressure and heat application can be the same, and therefore control over the pressure and temperature in manufacturing processes can be made easy. However, the same mixture does not have to be used for the insulating layers 101 and 109. For example, in order to improve the heat conduction properties of the insulating layer 109, the amount of the filler contained in the insulating layer 109 can be made larger than that of the insulating layer 101. That is, the composition of the mixture to be used for the insulating layer can be adjusted according to the heat conduction properties required.

### Embodiment 2

An electronic component built-in module in Embodiment 2 of the present invention is not different from the electronic component built-in module 100A as shown in FIG. 1 in terms of structure. This embodiment is different from Embodiment 1 in that in the processes for manufacturing an electronic component built-in module, the process of applying pressure and heat as described in FIG. 2(d), and the process of placing and fixing the heat sink 107 as described in FIG. 2(e) are carried out simultaneously.

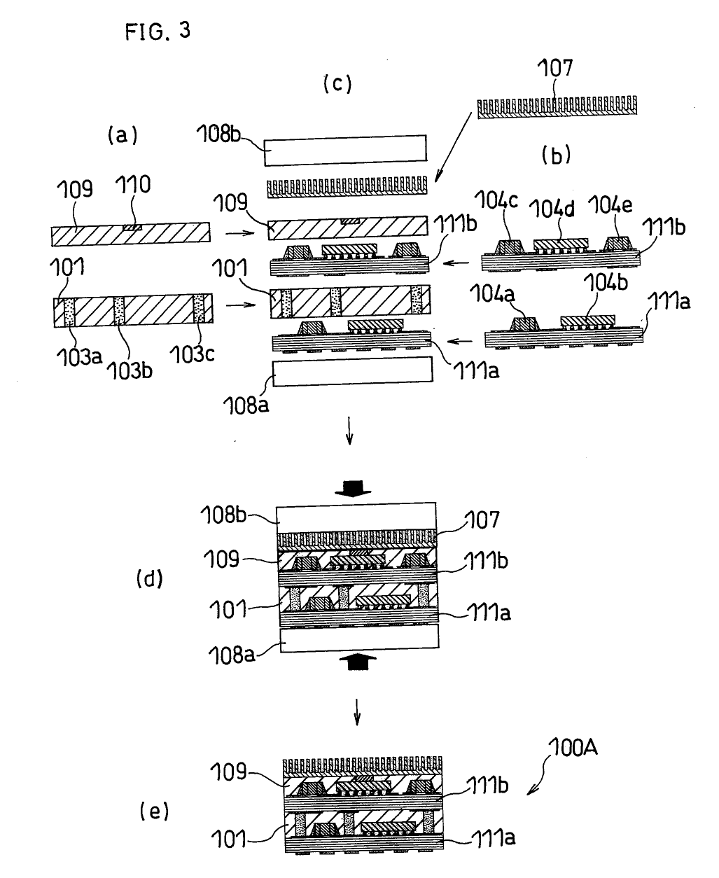

With reference to FIG. 3, a method for manufacturing an electronic component built-in module 100A in this embodiment is described. FIGS. 3(a) to 3(e) schematically show main processes for manufacturing an electronic component built-in module 100A in this embodiment. In FIG. 3, the same reference numerals are used for those elements having substantially the same function as those in FIG. 1 and FIG. 2, and detailed descriptions are omitted. This also applies to the following descriptions as well.

The processes (a) and (b) in FIG. 3 are the same as the processes (a) and (b) in FIG. 2, and therefore the descriptions are omitted. In the process shown in FIG. 3(c), similarly to the process shown in FIG. 2(c), on a wiring substrate 111a, an insulating layer 101, a wiring substrate 111b, and an insulating layer 109 are placed in order in a predetermined orientation at a predetermined position.

In the process shown in FIG. 3(c), further, a heat sink 107 is placed thereon, and then these wiring substrates and insulating layers are integrated by application of pressure and heat with heat-press plates 108a and 108b. After going through the process of the pressure and heat application as shown in FIG. 3(d), an excellently heat-releasing electronic component built-in module 100A as shown in FIG. 3(e) is obtained.

Based on this embodiment, the process of attaching the heat sink, which has been necessary conventionally, becomes unnecessary, and therefore the manufacturing costs can be reduced. Also, similarly to Embodiment 1, heat conduction with a broad contact area and little loss can be achieved.

### Embodiment 3

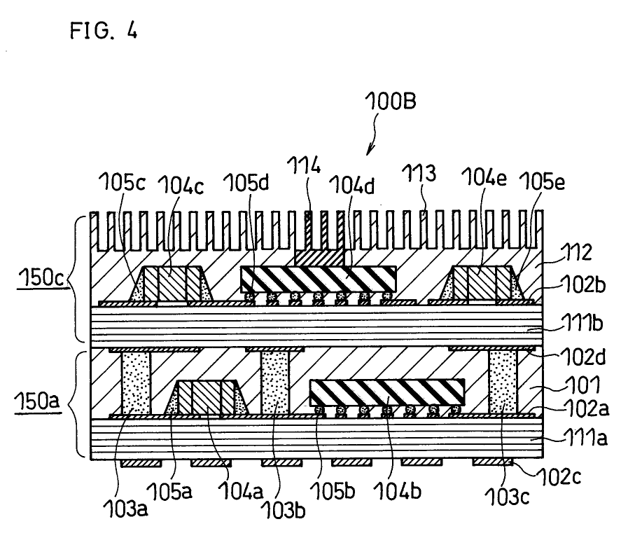

FIG. 4 shows a structure of an electronic component built-in module 100B in Embodiment 3 of the present invention. The electronic component built-in module 100B in this embodiment is different from the electronic component built-in module 100A as shown in FIG. 1 in terms of structure of the component built-in substrate disposed at the upper level. That is, in Embodiment 1, the insulating layer 109 forming the component built-in substrate 150b is provided separately from the heat sink 107. On the other hand, in the component built-in substrate 150c in this embodiment, the insulating layer 109 is integrally formed with the heat sink 107.

To be specific, as shown in FIG. 4, the electronic component built-in module 100B is not provided with the heat sink. Instead of the insulating layer 109 as shown in FIG. 1, an insulating layer 112 with a saw-toothed form 113 having a similar form with a heat sink surface formed at the heat-releasing face thereof is used. A thermal via 114 is also formed with the saw-toothed form, similarly to the insulating layer 112.

By thus forming the heat-releasing face of the insulating layer 112 with the saw-toothed form (serrate in the figure), the heat sink can be omitted. As a result, costs for the electronic component built-in module can be reduced, and also the process of fixing the heat sink to the insulating layer, which has been necessary in the conventional manufacturing processes, can be omitted.

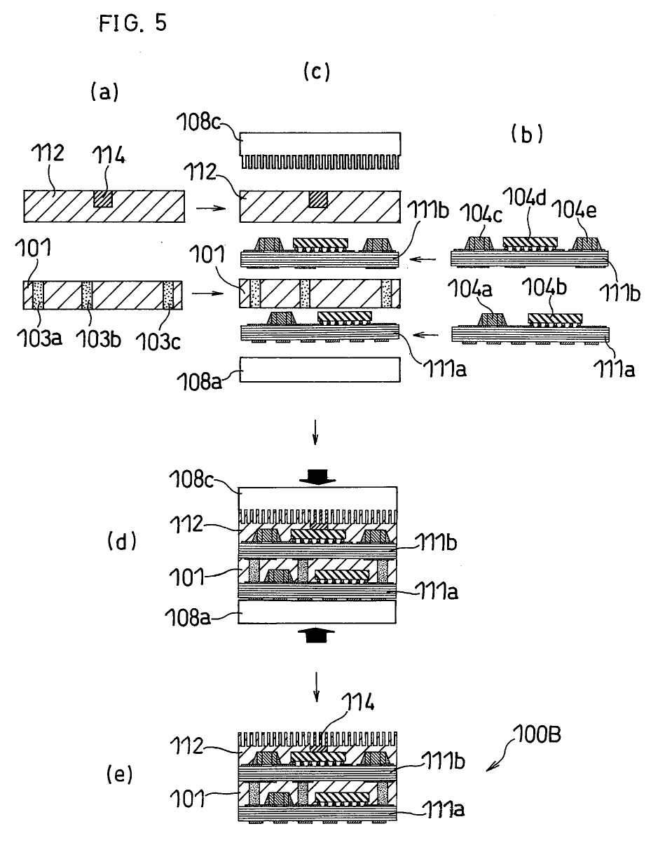

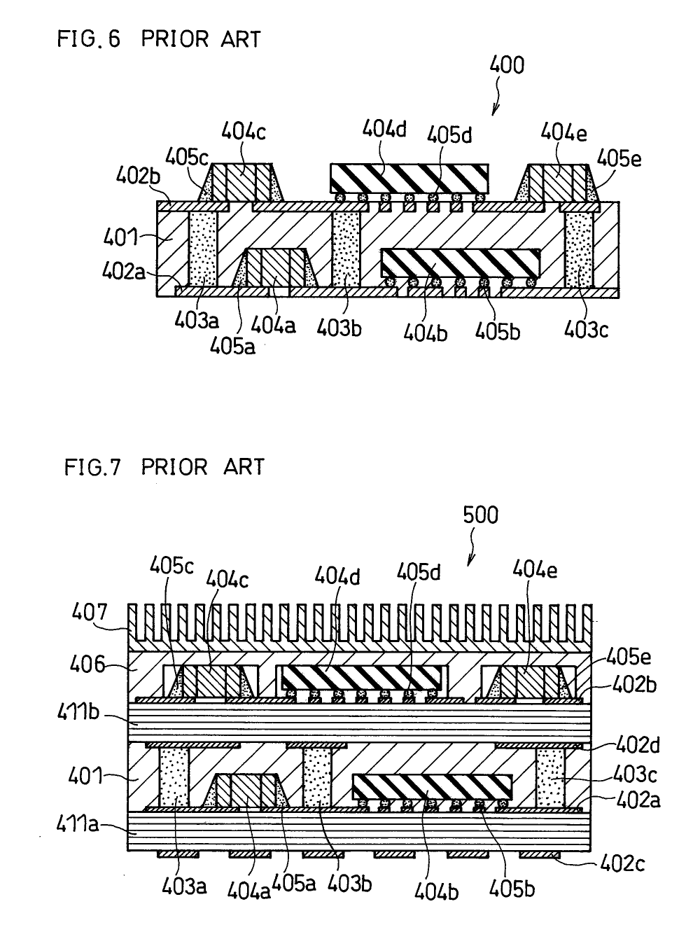

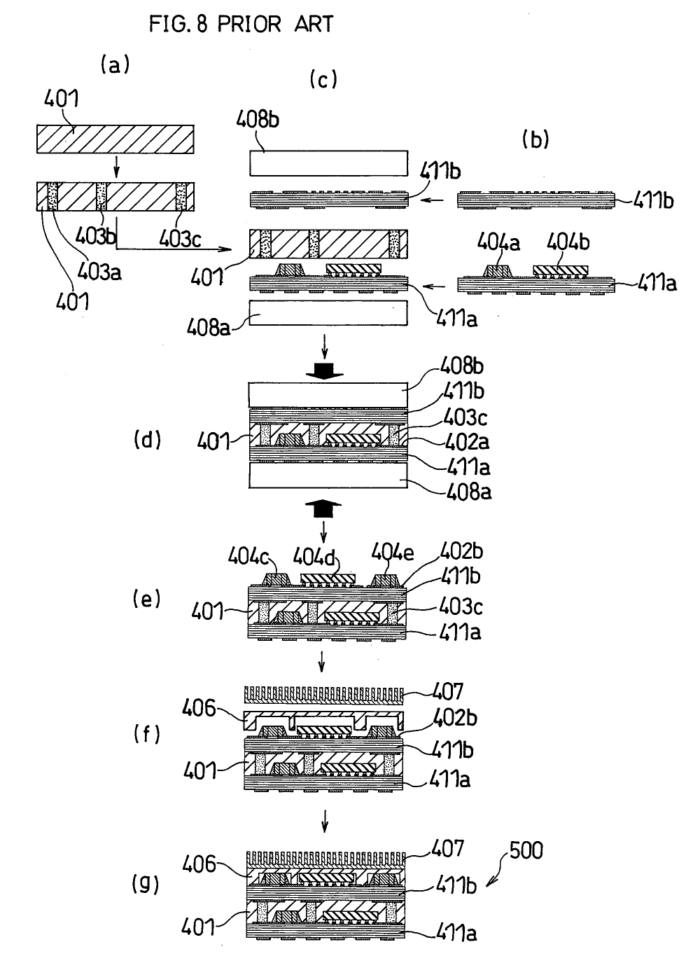

Then, with reference to FIG. 5, a method for manufacturing the electronic component built-in module 100B as shown in FIG. 4 is described. FIGS. 5(a) to 5(d) schematically show the main processes for manufacturing the electronic component built-in module 100B in this embodiment.

The processes (a) and (b) in FIG. 5 are the same as the processes (a) and (b) in FIG. 2, and therefore the descriptions are omitted. In the process of FIG. 5(c), in the same manner as the process of FIG. 2(c), an insulating layer 101, a wiring substrate 111b, and an insulating layer 112 are placed in order on a wiring substrate lila in a predetermined orientation and at a predetermined position.

In heat-press plates 108a and 108c used for applying pressure and heat, at the pressing-face of the heat-press plate 108c for applying pressure and heat to the insulating layer 112, a saw-toothed form (for example, serrate form) similar to the surface form of the heat sink is formed. By using the heat-press plate 108c having such a form, the surface form of the insulating layer 112 is molded to give the saw-toothed form similar to the heat sink.

After going through the process of applying pressure and heat in FIG. 5(d), as shown in FIG. 5(e), the electronic component built-in module 100B provided with heat-release measures is obtained.

Based on this embodiment, heat conduction with a broad contact area and little loss can be achieved, as in the case of Embodiment 1. Also, since the heat sink is unnecessary, the process for attaching the heat sink can be omitted, and further the number of components can be reduced.

As described above, an electronic component built-in module of the present invention can be widely applied in the field of portable devices, in which low-cost, high performance, and high quality electronic component built-in modules are required.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

1. An electronic component built-in module comprising a first component built-in substrate having built-in electronic components, a second component built-in substrate having built-in electronic components stacked on the first component built-in substrate, and a radiator attached on the second component built-in substrate,
wherein said first component built-in substrate comprises:
a first wiring layer with electronic components mounted on a main surface thereof, and
a first insulating layer,
which is mainly composed of a mixture containing an inorganic filler and a thermosetting resin, and
in which said electronic components mounted on said first wiring layer are embedded, and inner vias for electric connection are formed; and
said second component built-in substrate comprises:
a second wiring layer with electronic components mounted on a main surface thereof, and
a second insulating layer,
which is mainly composed of a mixture containing an inorganic filler and a thermosetting resin, and
in which said electronic components mounted on said second wiring layer are embedded.

2. The electronic component built-in module in accordance with claim 1,
wherein a recess portion is formed at a face contacting said radiator of said second insulating layer, and
a material with heat conduction properties is filled in said recess portion, said material having a higher degree of heat conduction than that of the mixture of which said second insulating layer is mainly composed.

3. The electronic component built-in module in accordance with claim 1, wherein the mixture of said first insulating layer and the mixture of said second insulating layer have the same composition.

4. The electronic component built-in module in accordance with claim 1, wherein said first wiring layer and said second wiring layer are formed respectively on multilayer wiring substrates.

5. The electronic component built-in module in accordance with claim 1, wherein said second insulating layer and said radiator are formed integrally.

6. The electronic component built-in module in accordance with claim 5, wherein said second insulating layer and said radiator are made of the same material.

7. A method for manufacturing an electronic component built-in module, comprising the steps of:
preparing first and second wiring layers with electronic components mounted on respective main surfaces thereof;
preparing a first insulating layer by molding a mixture containing an inorganic filler and a thermosetting resin in an uncured state into a sheet, forming through holes in said first insulating layer, and filling a thermosetting conductive material in an uncured state into said through holes;
preparing a second insulating layer by molding a mixture containing an inorganic filler and a thermosetting resin in an uncured state into a sheet;
stacking said first wiring layer, said first insulating layer, said second wiring layer, and said second insulating layer with positions of respective layers aligned, and the main surfaces of said first wiring layer and said second wiring layer with electronic components mounted facing upward; and
applying heat and pressure to said first wiring layer, said first insulating layer, said second wiring layer, and said second insulating layer stacked and sandwiched by a pair of heat-press plates for integration.

8. The method for manufacturing an electronic component built-in module in accordance with claim 7, further comprising a step of placing and fixing a radiator on top of the integrated body of said first wiring layer, said first insulating layer, said second wiring layer, and said second insulating layer.

9. The method for manufacturing an electronic component built-in module in accordance with claim 7, further comprising a step of forming a recess portion on a main surface of said second insulating layer, and filling a material with heat conduction in said recess portion, said material having a higher degree of heat conduction than that of the mixture of said second insulating layer.

10. The method for manufacturing an electronic component built-in module in accordance with claim 7, wherein in said step of applying heat and pressure with said pair of heat-press plates for integration, a radiator is further stacked on said second insulating layer, and pressure and heat are applied in such a state by said pair of heat-press plates.

11. The method for manufacturing an electronic component built-in module in accordance with claim 7, wherein a saw-toothed form is formed on a pressing side of one of said pair of heat-press plates contacting said second insulating layer.

12. The method for manufacturing an electronic component built-in module in accordance with claim 7, wherein said first wiring layer and said second wiring layer are formed respectively on multilayer wiring substrates.
